(19) United States
(12) Patent Application Publication
(10) Pub. No.: US 2024/0120315 A1
(43) Pub. Date: Apr. 11, 2024

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Ming-Fa Chen, Taichung City (TW); Tze-Chiang Huang, Saratoga, CA (US); Yun-Han Lee, Hsinchu County (TW); Lee-Chung Lu, Taipei (TW)

(73) Assignee: Taiwan Semiconductor Manufacturing Company, Ltd., Hsinchu (TW)

(21) Appl. No.: 18/169,579

(22) Filed: Feb. 15, 2023

Related U.S. Application Data
(60) Provisional application No. 63/414,750, filed on Oct. 10, 2022.

(51) Int. Cl. H01L 25/065; H01L 23/00; H01L 23/31; H01L 23/48; H01L 23/538; H01L 25/00; H01L 25/18; H10B 80/00

(52) U.S. Cl. CPC H01L 25/0652; H01L 23/3185; H01L 23/481; H01L 23/538; H01L 23/5384; H01L 24/05; H01L 24/06; H01L 24/08; H01L 25/18; H01L 25/50; H10B 80/00; H01L 24/13; H01L 2224/0401; H01L 2224/0557; H01L 2224/05571; H01L 2224/05624; H01L 2224/05647; H01L 2224/05666; H01L 2224/05684; H01L 2224/06181; H01L 2224/08147; H01L 2224/08221; H01L 2224/13111; H01L 2224/13124; H01L 2224/13139; H01L 2224/13144; H01L 2224/13147; H01L 2224/13164

(57) ABSTRACT

A semiconductor package includes a first semiconductor die and a second semiconductor die disposed laterally adjacent one another. The semiconductor package includes a semiconductor bridge overlapping a first corner of the first semiconductor die and a second corner of the second semiconductor die. The semiconductor bridge electrically couples the first semiconductor to the second semiconductor die. The semiconductor package includes a third semiconductor die and a fourth semiconductor die electrically coupled to the first semiconductor die and the second semiconductor die, respectively. The semiconductor bridge is interposed between the third semiconductor die and the fourth semiconductor die.

### CROSS-REFERENCE TO RELATED APPLICATIONS

The present application claims the benefit of and priority to U.S. Provisional Patent App. No. 63/414,750, filed Oct. 10, 2022, the entire disclosure of which is incorporated by reference herein.

### BACKGROUND

Semiconductor devices are ubiquitous in several applications and devices throughout most industries. For example, consumer electronics devices such as personal computers, cellular telephones, and wearable devices may contain several semiconductor devices. Similarly, industrial products such as test instruments, vehicles, and automation systems frequently comprise a large number of semiconductor devices. As semiconductor manufacturing improves, semiconductors continue to be used in new applications which, in turn, leads to increased demands of semiconductor performance, cost, reliability, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts a planar top view of a portion of an example semiconductor device, in accordance with some embodiments of the present disclosure.

FIGS. 2 and 3 each depict a cross-sectional view along line AA′ of the example semiconductor device of FIG. 1, in accordance with some embodiments of the present disclosure.

FIGS. 4 and 5 each depict a schematic of a cross-sectional view of an example a cross-sectional view, in accordance with some embodiments of the present disclosure.

FIG. 6 depicts a cross-sectional view along line BB′ of the example semiconductor device of FIG. 1, in accordance with some embodiments of the present disclosure.

FIG. 7 depicts a planar top view of a portion of an example semiconductor device, in accordance with some embodiments of the present disclosure.

FIGS. 8, 9, 10, and 11 each depict a cross-sectional view along line AA′ of the example semiconductor device of FIG. 7, in accordance with some embodiments of the present disclosure.

FIG. 12 depicts a cross-sectional view along line BB′ of the example semiconductor device of FIG. 7, in accordance with some embodiments of the present disclosure.

FIGS. 13 and 14 each depict a planar top view of a portion of an example semiconductor device, in accordance with some embodiments of the present disclosure.

FIGS. 15 and 16 each depict a schematic cross-sectional view of a portion an example semiconductor device, in accordance with some embodiments of the present disclosure.

FIG. 17 is a flow diagram of a method for the fabrication of a semiconductor device, in accordance with some embodiments of the present disclosure.

FIG. 18 depicts a cross-sectional view along line AA′ of the example semiconductor device of FIG. 7, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, semiconductor devices are fabricated by a combination of front end of line (“FEOL”) processes, which manufacture semiconductor (e.g., silicon) dies, and back end of line (“BEOL”) processes, which package one or more of these dies into a semiconductor device that can interface with other devices. For example, the package may combine a plurality of semiconductor dies and can be configured to be attached to a printed circuit board or other interconnected substrate, which may, in turn, allow the plurality of semiconductor dies of the semiconductor device to interface with additional semiconductor devices or other devices, power sources, communication channels, etc.

Physical demands for device miniaturization, increasing connectedness, and power efficiency are driving increases to semiconductor device density. Some of this increase in density can be attributed to improvements in the FEOL processes, including die miniaturization. Modern packaging technologies (e.g., package on package (PoP), Fan-Out packaging (FO), etc.) are also driving miniaturization, intercommunication, power savings and other improvements. The one or more dies of these modern packages may be interconnected or connected to package inputs and/or outputs (I/O) by bond wires, through-silicon (or through-substrate) vias (TSVs), interconnect structures (e.g., vias and conductive lines disposed in various dielectric layers) coupled to the silicon dies, hybrid bonds via a bonding interface layer, solder bumps, other bonding methods, or combinations thereof. While such connections use sophisticated techniques, further improvements are needed to advance the state of the art.

Semiconductor devices can include a plurality of semiconductor dies. Various semiconductor dies can be bonded (or otherwise coupled) together to form a heterogeneous chip. For example, dies can be bonded front-to-back or back-to-back such that an active surface of each die can receive one or more signals from an adjacent, bonded die, or by a TSV of the die or of an adjacent, bonded die. Semiconductor bridges can be formed between various semiconductor dies or chips to pass signals such as power delivery network signals (PDN), clocks, address, data signals, etc. Some semiconductor devices can include one or more non-adjacent (i.e., offset along both the X-direction and the Y-direction in a top view) chips or dies with an interconnection therebetween such that the interconnection circuit can include multiple semiconductor bridges. Such interconnection circuits can result in latency, signal integrity issues, or an IR drop which is greater than a target value. A redistribution structure including a plurality of conductive features in dielectric layers can be formed over one or more the dies. Such distribution structure may be formed on a front or a back side of the dies.

Semiconductor dies, as used herein, refers to as a portion of a semiconductor wafer having disposed thereupon one or more active circuits such as transistor logic, analog devices such as RF or filtering elements, diodes, other circuit components, or combinations thereof. A plurality of conductive features or metallization patterns (e.g., vias and conductive lines) between the active surfaces can be disposed in one or more dielectric layers to form a multi-layer interconnect structure (MLI). A plurality of dies can be combined to form a larger chip such as memory stacks, heterogeneous chips (including one or more die types), or other chips. Die types can include a process node of a die or a function of a die (e.g., PDN, processing, graphics, volatile memory, non-volatile memory, etc.).

A plurality of semiconductor dies (or “dies” for short) can be joined (e.g., bonded or interconnected) vertically (e.g., at least partially overlap in a z-direction) to form a stack, and a plurality of stacks may be joined and subsequently isolated to form a package. In some instances, interconnected dies may be bonded by connection of a TSV or other die-to-die connections such as hybrid bonding, solder bumps, other connections, or combinations thereof. In some embodiments, the die connection includes a bonding interface layer having a conductive element (also referred to as a bond pad) disposed in a dielectric layer, where bond pads of one dies are bonded to bond pads of another dies. The conductive element may include copper, aluminum, or other materials. In some embodiments, an intermediate material (e.g., a solder bump) is disposed between the interconnected dies. The presence of a solder bump can aid the self-alignment of the die connections. For example, the solder bump may allow slightly offset connectors to maintain a connection (e.g., a mechanical, electrical, or thermal connection). In some embodiments, no intermediate material may be present for at least some junctions. For example, the dies can be connected by copper-to-copper connections (which may be suitable for increased connection density, relative to at least some bump technologies). In some embodiments, the die connection includes an MLI. For example, the TSV of a die may terminate on a portion of the MLI, which includes a plurality of vias and conductive lines in dielectric layers.

The present disclosure provide various embodiments each including a plurality of stacks of interconnected dies separated by insulation structures (e.g., gap-fill layers), where the plurality of stacks are laterally (e.g., along the X-direction and/or the Y-direction) and/or vertically (e.g., along the Z-direction) interconnected by at least one semiconductor bridge to provide die-to-die communication between dies of different stacks. As provided herein, the dies within a stack are bonded in a front-to-back configuration for illustrative purposes, though other configurations, such as front-to-front configuration, may also be applicable. In some embodiments, the semiconductor bridge overlaps and electrically couples to corners of a plurality of dies to provide four-way die-to-die communication, such that multiple conduction paths may be established laterally and/or vertically. In some embodiments, each stack includes two interconnected dies. In some embodiments, each stack includes three interconnected dies.

In some embodiments, the semiconductor bridge includes TSVs that each electrically couple a die disposed over the semiconductor bridge with a die disposed under the semiconductor bridge. In some embodiments, the semiconductor bridge includes a redistribution structure along its back side to provide lateral connections between dies disposed in different stacks. In some embodiments, dies on a bottom tier of one or more of the stacks coupled by the semiconductor bridge each include a redistribution structure along their respective back sides to provide lateral connections across different dies disposed in the same tier. Advantageously, the die-to-die connections provided by the TSVs in the semiconductor bridge, the back side redistribution structure in the semiconductor bridge, and/or the back side redistribution structure in the dies of the bottom tier may shorten the conduction paths (e.g., measured as a Manhattan distance) between various dies, leading to gain in die-to-die latency and overall gain in device performance.

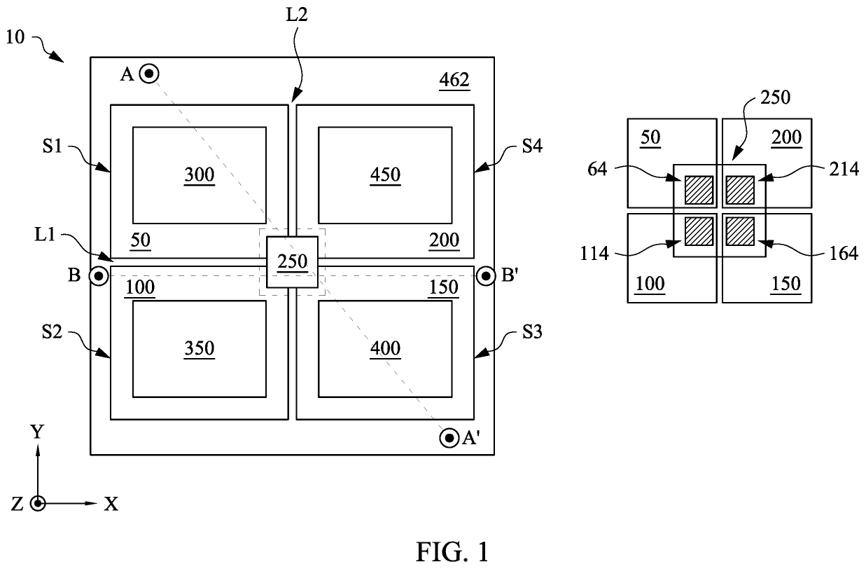

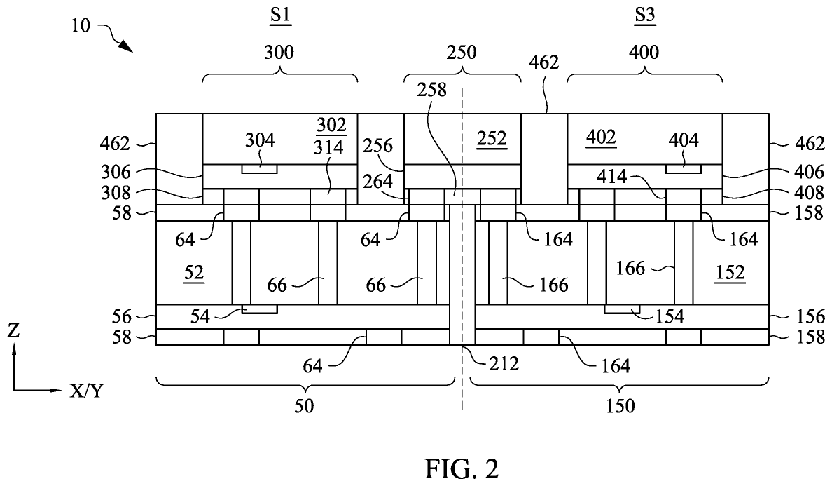

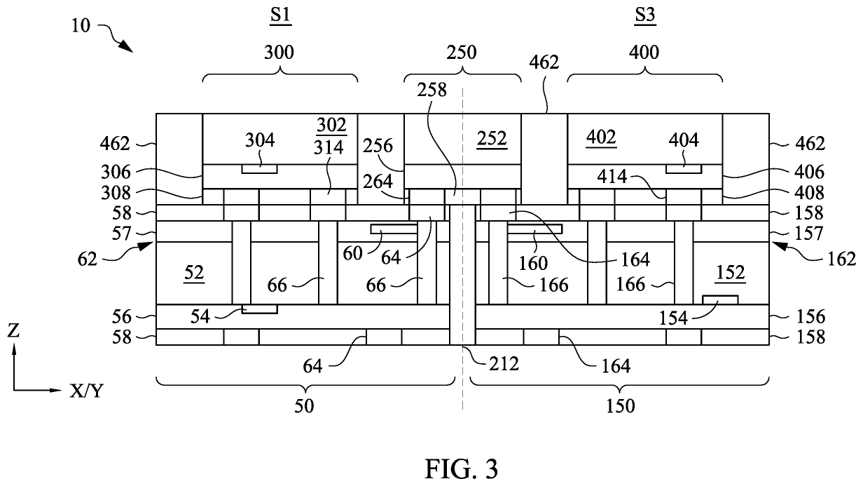

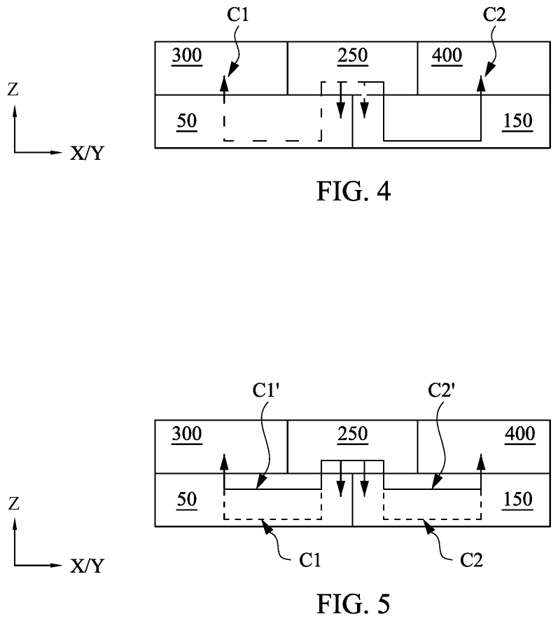

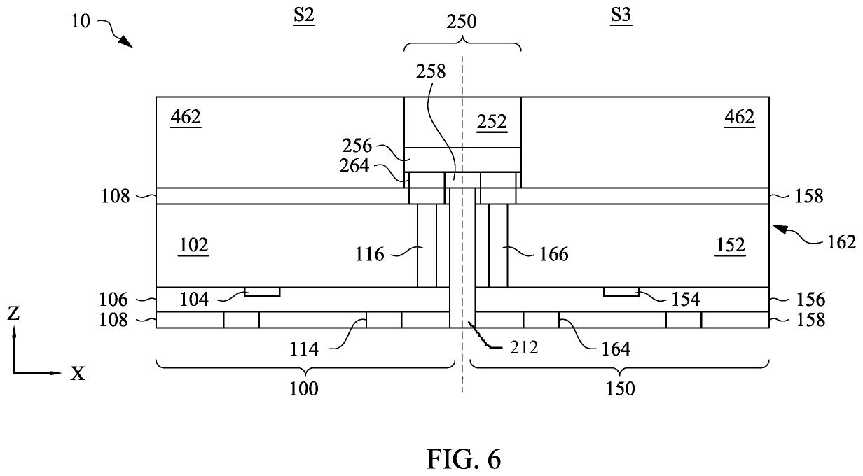

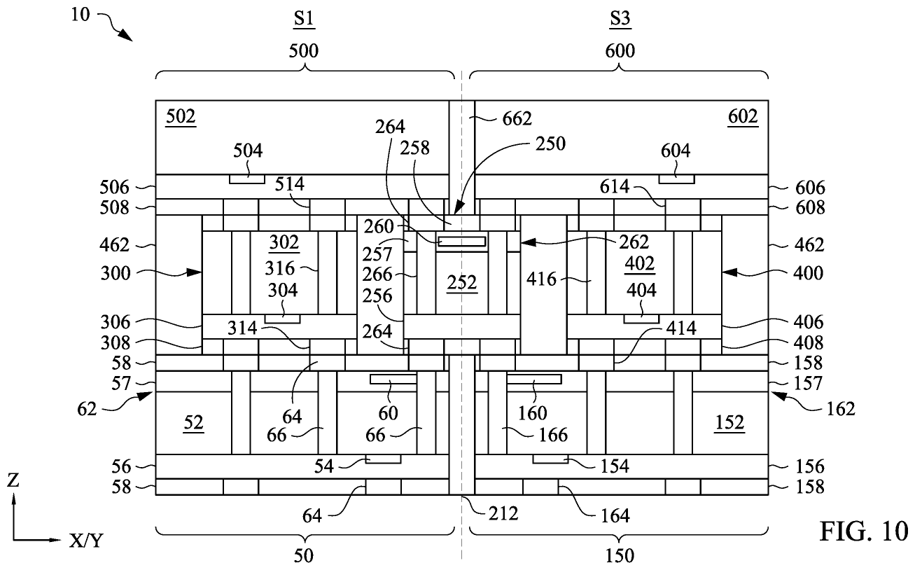

FIGS. 1-12 and their corresponding discussion below are directed to various embodiments of an example semiconductor package component (or “package component” for short) 10, in accordance with some aspects of the present disclosure. FIGS. 1, 5, 11, and 12 are top views of the package component 10 in the X-Y plane; FIGS. 2 and 3 are cross-sectional views of the package component 10 along line AA′ as shown FIG. 1; FIG. 4 is a cross-sectional view of the package component 10 along line BB′ as shown in FIG. 1; FIGS. 6-9 are cross-sectional views of the package component 10 along line AA′ as shown FIG. 5; and FIG. 10 is a cross-sectional view of the package component 10 along line BB′ as shown in FIG. 5.

For embodiments depicted in FIGS. 1, 5, 11, and 12, gap-fill layers, such as gap-fill layer 462 as shown, between adjacent dies are omitted for purposes of clarity. For embodiments depicted in FIGS. 2-4 and 6-9, the package component 10 is shown as having an “upward” direction aligned with the Z-direction. In some examples (not depicted), the package component 10 may be configured to interface mechanically, thermally, or electrically, with a circuit board assembly or another substrate at a top surface (i.e., along the “upward” direction) and/or a bottom surface (i.e., along a “downward” direction) of the package component 10.

Referring to FIG. 1, the package component 10 includes stacks S1, S2, S3, and S4 arranged across the X-Y plane and a semiconductor bridge (alternatively referred to as a silicon bridge or a bridge die) 250 interconnecting the stacks S1-S4 laterally (e.g., along the X-direction and/or the Y-direction) and vertically (e.g., along the Z-direction), where the stacks S1 and S4 are separated from the stacks S2 and S3 by a horizontal scribe line L1 and the stacks S1 and S2 are separated from the stacks S3 and S4 by a vertical scribe line L2.

In the present embodiments, the stacks S1-S4 are isolated by gap-fill layers, such as the gap-fill layer 462, that fill the horizontal scribe line L1, the vertical scribe line L2, and surround each stack S1-S4. In the depicted embodiments, each stack S1-S4 includes a first die and a second die over and coupled (electrically and physically) to the first die. For example, the stack S1 includes a die 300 bonded (or coupled) to a die 50; the stack S2 includes a die 350 bonded to a die 100; the stack S3 includes a die 400 bonded to a die 150; and the stack S4 includes a die 450 bonded to a die 200. As such, the dies 50, 100, 150, and 200 are collectively considered as to form a bottom tier of the package component 10 and the dies 300, 350, 400, and 450 are collectively considered as to form a top tier of the package component 10 over the bottom tier.

The dies within each stack S1-S4 may be bonded by any suitable bonding schemes, such as by one or more TSVs, a direct bonding method (e.g., hybrid bonding), via an intermediate material (e.g., a solder bump), other suitable schemes, or combinations thereof. Furthermore, the dies within each stack S1-S4 may each include an active circuit or an inactive circuit. In some instances, both dies within each stack S1-S4 include active circuits, though the active circuits differ in types and/or functions.

In the present embodiments, as shown in detail of a portion of the package component 10 within dotted enclosure, the semiconductor bridge 250 is positioned to overlap a corner of each of the dies 50-200, where the dies 50-200 are arranged in a corner-to-corner configuration. In other words, the semiconductor bridge 250 is configured to be electrically coupled to a portion of each of the dies 50-200 in a region where the horizontal scribe line L1 intersects with the vertical scribe line L2, thereby providing die-to-die connection (or communication) between more than two dies. In the present embodiments, the semiconductor bridge 250 is physically bonded (or coupled) to the dies 50-200 by conductive connectors (e.g., bond pads) 64, 114, 164, and 214, respectively. Furthermore, the semiconductor bridge is interposed between corners of the dies 300-450.

In some embodiments, the semiconductor bridge 250 has a structure similar to one or more of the dies (e.g., the dies 50-200) to which it is electrically coupled. In this regard, the semiconductor bridge 250 may include one or more conductive elements over a semiconductor substrate. For example, the semiconductor bridge 250 may include MLIs disposed over a surface of the semiconductor substrate. In some embodiments, the semiconductor bridge 250 is an inactive die, i.e., free of any active circuits, though the present disclosure is not limited as such. The semiconductor bridge 250 may be of a higher density than other package connections. Some connections can extend through a plurality of semiconductor bridges (e.g., bridges between or within stacks). Each connection through a semiconductor bridge can include the distance of the bridge as well as one or more via structures connecting to the semiconductor bridge, and any additional routing length. Some connections through a semiconductor bridge (e.g., a plurality of semiconductor bridges) can be associated with a latency, IR drop, or another signal integrity concern.

FIG. 2 depicts a cross-sectional view of the package component 10 along line AA′ that spans across the stack S1, the semiconductor bridge 250, and the stack S3, i.e., diagonally across the package component 10 as shown in the top view.

In some embodiments, the die 50 includes a device feature 54 disposed over a front side (i.e., an active surface) of a semiconductor substrate 52; an MLI 56 disposed over the device feature 54, which includes a plurality of conductive features such as vias and conductive lines, disposed in one or more dielectric layers and electrically coupled to the device feature 54; and TSVs 66 extending through the semiconductor substrate 52 to connect components disposed over a back side (i.e., an inactive surface) of the semiconductor substrate 52 with the device feature 54 and those over the front side of the semiconductor substrate 52. The die 50 may be bonded to overlaying dies (e.g., the die 300 and the semiconductor bridge 250) via a bonding layer 58, which may include a dielectric material, and bond pads 64, which includes a conductive material, disposed in the bonding layer 58. In this regard, the die 50 is electrically coupled to both the die 300 and the semiconductor bridge 250. It is noted that the bonding layer 58 and the bond pads 64 may together be referred to as a bonding interface in the following description.

The die 150 may include similar components as the die 50. For example, the die 150 may include a semiconductor substrate 152; a device feature 154 disposed over a front side of the semiconductor substrate 152; an MLI 156 electrically coupled to the device feature 154; and TSVs 166 extending through the semiconductor substrate 152. The die 150 interfaces with the overlaying dies (e.g., the die 400 and the semiconductor bridge 250) via a bonding layer 158 and bond pads 164 disposed in the bonding layer 158 to connect with a corresponding bond pad 264 of the semiconductor bridge 250 and with corresponding bond pads 414 of the die 400. As depicted herein, the dies 50 and 150 are separated by a portion of a gap-fill layer 212, which is formed to laterally surround the dies 50 and 150.

Similarly, the die 300 may include a semiconductor substrate 302; a device feature 304 disposed over a front side of the semiconductor substrate 302; and an MLI 306 electrically coupled to the device feature 304. The die 300 interfaces with the underlying die 50 via a bonding layer 308 and bond pads 314 disposed in the bonding layer 308. The die 400 similarly may include a semiconductor substrate 402; a device feature 404 disposed over a front side of the semiconductor substrate 402; and an MLI 406 electrically coupled to the device feature 404. The die 400 interfaces with the underlying die 150 via a bonding layer 408 and bond pads 414 disposed in the bonding layer 408 to connect with a corresponding bond pad 164 of the die 150.

It is noted that one or more circuit components discussed herein may be omitted and additional circuit components may be included in one or more of the dies of the package component 10 depicted herein. For example, one or more of the dies of the package component 10 do not include any active device features, i.e., the one or more dies may be configured as inactive or dummy dies.

Still referring to FIG. 2, the semiconductor bridge 250 may include a semiconductor substrate 252 and an MLI 256 disposed over a front side of the semiconductor substrate 252. The semiconductor bridge 250 interfaces with the dies 50 and 150 via a bonding layer 258 and bond pads 264 disposed in the bonding layer 258 to electrically couple the underlying dies 50 and 150 together. In the present embodiments, the semiconductor bridge 250 straddles the portion of the gap-fill layer 212 to connect with the dies 50 and 150 by way of hybrid bonding, for example, at the bonding interface. For embodiments in which the semiconductor bridge 250 is free of any active device as shown herein, the MLI 256 is configured to provide routing between the dies 50 and 150, which are disposed in stacks S1 and S3 that are arranged in a corner-to-corner configuration, through the bonding interface that includes various bonding layers (e.g., the bonding layers 58, 158, and 258) and bond pads (e.g., the bond pads, 64, 164, and 264). Additionally, the semiconductor bridge 250 is laterally (along the X-direction and the Y-direction) interposed between the dies 300 and 400 and is separated from the dies 300 and 400 by portions of the gap-fill layer 462.

Referring to FIGS. 1 and 2 collectively, a combination of various bonding interfaces between dies and between a die and the semiconductor bridge 250, TSVs in one or more dies, and MLIs of various dies allows a conduction path be established between dies of different stacks and in different layers, where corners of the stacks are overlapped with the semiconductor bridge 250. For example, through the bonding interfaces between the die 300 and the die 50, between the die 150 and the die 400, between the die 50 and the semiconductor bridge 250, and between the die 150 and the semiconductor bridge 250, the TSVs 66 and 166, and the MLIs 56, 156, and 256, communication may be established between the die 50 and the die 150 and between the die 300 and the die 400. Similarly, though not depicted herein, communication may be established between the die 100 and the die 200 and between the die 350 and the die 450 as they are arranged analogously to the depicted dies 50, 150, 300, and 400. Accordingly, by positioning the semiconductor bridge 250 over corners, rather than along edges, of the dies, communication between the dies may be extended from two-way to four-way, allowing improved latency gain between non-adjacent dies.

FIG. 3 depicts an embodiment of the package component 10 that is similar to that depicted in FIG. 2, with the exception that the dies on the bottom tier of the package component 10 underlying the semiconductor bridge 250 each further include a redistribution structure for providing additional lateral communication across a back side of such dies. For example, the back side of the die 50 includes a redistribution feature 60 disposed in a dielectric layer 57, which together form a redistribution structure 62, and the back side of the die 150 includes a redistribution feature 160 disposed in a dielectric layer 157, which together form a redistribution structure 162.

The redistribution structures 62 and 162 may each include one or more conductive features (or metallization patterns) extending laterally across the X-Y plane and vertically along the Z direction in one or more dielectric layers. For example, the conductive features may include vertical vias and horizontal conductive lines to provide routing between device(s) formed along an active surface of the semiconductor substrate and other circuit components. The redistribution structures 62 and 162 may each provide connection between adjacent and non-adjacent stacks of interconnected dies.

In the present embodiments where the dies of each stack are interconnected in a front-to-back configuration, the redistribution structures disposed along back sides of the dies on the bottom tier of the package component 10 provides shortened conduction paths between dies of non-adjacent stacks for improved device gain. For example, the redistribution structures 62 and 162 provide conduction paths along a back side of each of the dies 50 and 150, i.e., near the dies' bonding interface with the front side of the semiconductor bridge 250. As such, signal communication between the die 300 of the stack S1 and the dies (e.g., either the die 150 or the die 400) of the stack S3 would not rely on the TSVs 66 through the semiconductor substrate 52, shortening a distance (e.g., a Manhattan distance) for improved average die-to-die latency gain of the package component 10.

In some existing implementations, the dies 50-200 may include an alignment mark at each die's corners for purposes of maintaining the dies' relative positions during packaging processes. Such alignment mark may prevent the dies being positioned near one another, thereby inadvertently increasing the conduction paths between the dies. By directly bonding the semiconductor bridge 250 to the dies 50-200, however, the alignment marks are no longer necessary and may therefore be removed to further shorten the conduction paths between the dies.

FIG. 4 schematically illustrates a conduction path C1 between the dies 150 and 300 and a conduction path C2 between the dies 50 and 400, according to the embodiment depicted in FIG. 2, and FIG. 5 schematically illustrates a conduction path C1′ between the dies 150 and 300 and a conduction path C2′ between the dies 50 and 400, according to the embodiment depicted in FIG. 3. For comparison purposes, the conduction paths C1 and C2 are superimposed onto the conduction paths C1′ and C2′ in FIG. 5. As shown, due to the presence of the redistribution structures 62 and 162 in the dies 50 and 150, respectively, the conduction path C1′ is shorter than the conduction path C1 and the conduction path C2′ is shorter than the conduction path C2′. In some examples, the improved average die-to-die latency gain with the shortened conduction path leads to a system performance gain of about 4% to about 8%.

FIG. 6 illustrates a cross-sectional view of the package component 10 along line BB′ as shown in FIG. 1. In the depicted embodiment, the semiconductor bridge 250 is disposed over and electrically coupled to the dies 100 and 150, which are isolated by the gap-fill layer 212, and interposed between portions of the gap-fill layer 462. In this regard, the semiconductor bridge 250 electrically couples the die 100 to the die 150, similar to the embodiment depicted in FIG. 2. As such, in addition to affording four-way die-to-die communication between dies of non-adjacent stacks (e.g., the stacks S1 and S3 or the stacks S2 and S4), the semiconductor bridge 250 also allows two-way communication between dies in the same tier of laterally adjacent (i.e., side-by-side) stacks (e.g., the stacks S2 and S3).

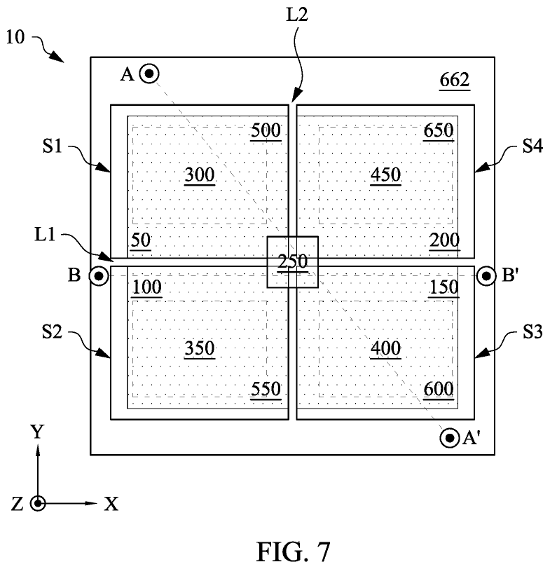

FIG. 7 depicts an embodiment of the package component 10 that is similar to that depicted in FIG. 1, with the exception that each of the stacks S1-S4 includes three, instead of two dies vertically bonded to one another. For example, the stack S1 includes a die 500 bonded to the die 300, which is further bonded to the die 50; the stack S2 includes a die 550 bonded to the die 350, which is further bonded to the die 100; the stack S3 includes a die 600 bonded to the die 400, which is further bonded to the die 150; and the stack S4 includes a die 650 bonded to the die 450, which is further bonded to the die 200. As such, the dies 50, 100, 150, and 200 are collectively considered as to form a bottom tier of the package component 10, the dies 300, 350, 400, and 450 are collectively considered as to form a middle tier of the package component 10 over the bottom tier, and the dies 500, 550, 600, and 650 collectively considered as to form a top tier of the package component 10 over the middle tier.

In the present embodiments, the semiconductor bridge 250 is electrically coupled to the dies 50-200 in a manner similar to that discussed above with respect to FIG. 1. For example, the semiconductor bridge 250 overlaps and is electrically coupled to a corner of each of the dies 50-200. The dies 500-650 each overlap and are physically and electrically coupled to a corner of the semiconductor bridge 250. Furthermore, the dies 500-650 are physically and electrically coupled to underlying dies 300-450 in their respective stacks.

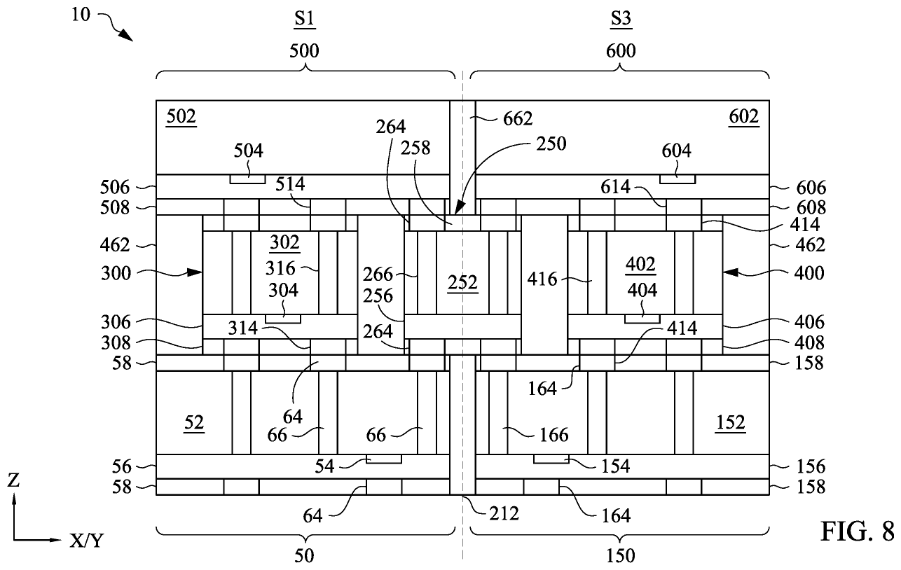

Referring to FIG. 8, the dies 500-650 may each be bonded to the underlying semiconductor bridge 250 and the dies in their respective stacks by a hybrid bonding process to form various bonding interfaces that include bond pads (e.g., bond pads 514 and 614) disposed in their respective bonding layers (e.g., bonding layers 508 and 608). The die 500 may include a semiconductor substrate 502; a device feature 504 disposed over the semiconductor substrate 502; and an MLI 506 disposed over and electrically coupled the device feature 504. The die 600 may similar include a semiconductor substrate 602; a device feature 604 disposed over the semiconductor substrate 6502; and an MLI 606 disposed over and electrically coupled to the device feature 604. Though not depicted, the dies 550 and 650 may include similar components as the dies 500 and/or 600 and may be bonded to the underlying semiconductor bridge 250 and the dies 350 and 450 in a manner similar to that depicted for the dies 500 and 600. In the present embodiments, the dies 500-650 are isolated by gap-fill layer 662. Additionally, the dies 300 and 400 (as well as dies 350 and 450) may each further include one or more TSVs 316 and 416, respectively, to interconnect the dies 50 and 500 and dies 150 and 600, respectively.

It is noted that one or more circuit components discussed herein may be omitted and additional circuit components may be included in one or more of the dies of the package component 10 depicted herein. For example, one or more of the dies of the package component 10 do not include any active device features, i.e., the one or more dies may be configured as inactive or dummy dies.

In the present embodiments, still referring to FIG. 8, the semiconductor bridge 250 further includes TSVs 266 that extends through the semiconductor substrate 252 to connect circuit components over the back side of the semiconductor bridge 250 with those over the front side of the semiconductor bridge 250, where the electrically coupled components include dies in the same stack. For example, the TSVs 266 are configured to electrically couple the dies 500 and 600 to the dies 50 and 150, respectively.

In addition to such vertical interconnection, the combination of the TSVs and the MLI in the semiconductor bridge 250 allows the dies in different tiers of non-adjacent stacks be connected along a shortened conduction path. For example, a conduction path between the die 50 and the die 600 extends through the TSV 266 to bypass the semiconductor substrates 152 and 402, and a conduction path between the die 150 and the die 500 extends through the TSV 266 to bypass the semiconductor substrates 52 and the semiconductor substrate 302, thereby improving the latency gain of the package component 10. Analogously, though not depicted herein, a conduction path between the die 100 and the die 650 extends through the TSV 266 to bypass the semiconductor substrates of the dies 200 and 450, and a conduction path between the die 200 and the die 550 extends through the TSV 266 to bypass the semiconductor substrates of the dies 100 and 350. Accordingly, the four-way die-to-die communication established by positioning the semiconductor bridge 250 over corners, rather than along edges, of the dies, may also be extended to package components including dies arranged in three-tiered structures.

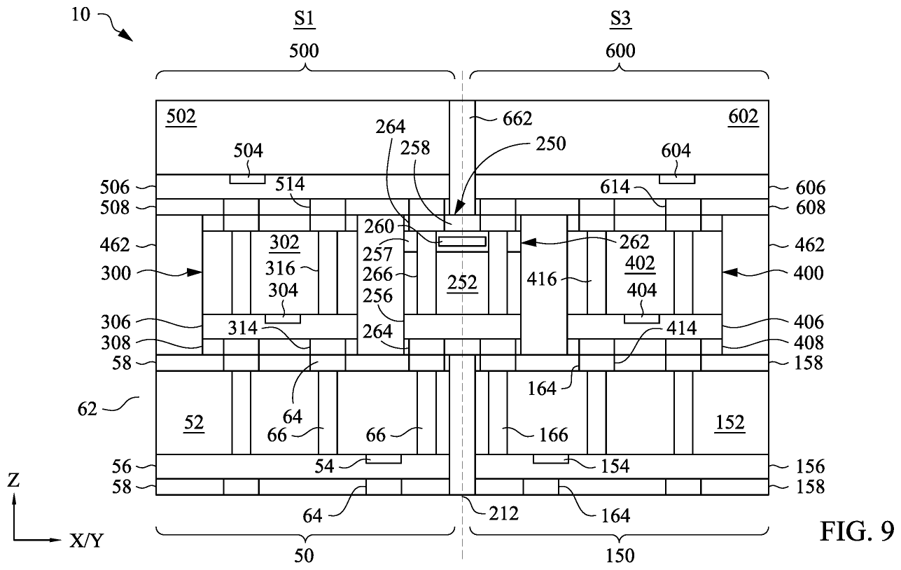

FIG. 9 depicts an embodiment of the package component 10 that is similar to that depicted in FIG. 8, with the exception that the semiconductor bridge 250 further includes a redistribution structure along its back side to provide direct lateral communication across dies disposed over and electrically coupled to the semiconductor bridge 250. For example, in the present embodiments, the back side of the semiconductor bridge 250 includes a redistribution feature 260 disposed in a dielectric layer 257, which together form a redistribution structure 262. In this regard, the redistribution structure 262 provides communication along a shortened conduction path between the adjacent dies 500 and 600, which are bonded to the back side of the semiconductor bridge 250, bypassing the semiconductor substrate 252, the MLI 256, and the TSVs 266 of the semiconductor bridge 250. In some embodiments, the redistribution structure 262 is similar to the redistribution structures 62 and 162 discussed in detail above. In some embodiments, the inclusion of the redistribution structure 262 is optional in the package component 10.

FIG. 10 depicts another embodiment of the package component 10 that is similar to that depicted in FIG. 8, with the exception that the dies on the bottom tier of the package component 10 underlying the semiconductor bridge 250 each further include a redistribution structure to provide additional lateral communication across a back side of such dies. For example, the back side of the die 50 includes the redistribution structure 62, and the back side of the die 150 includes the redistribution structure 162, similar to that depicted in FIG. 3.

As discussed in detail above, the redistribution structures 62 and 162 disposed along back sides of their respective dies provide shortened conduction paths between dies of non-adjacent stacks for improved device gain. For example, the redistribution structures 62 and 162 provide conduction paths along a back side of each of the dies 50 and 150, i.e., near the dies' bonding interface with the front side of the semiconductor bridge 250. As such, signals between the die 300 of the stack S1 and the dies (e.g., either the die 150 or the die 400) of the stack S3 would bypass the TSVs 66 through the semiconductor substrate 52, shortening the conduction path for improved die-to-die latency gain of the package component 10. In some instances, the improved average die-to-die latency gain with the shortened conduction path leads to a system performance gain of about 7% to about 15%. In some embodiments, the inclusion of the redistribution structures along the back sides of the dies on the bottom tier of the package component 10 is optional.

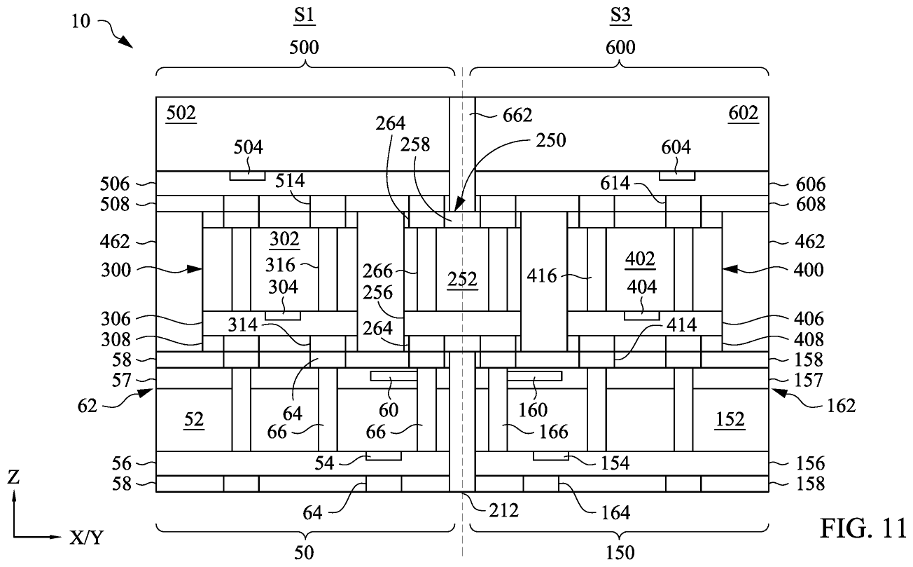

FIG. 11 depicts an embodiment of the package component 10 that is similar to that depicted in FIG. 10, with the exception that the redistribution structure 262 along the back side of the semiconductor bridge 250 is excluded, and the package component 10 includes the redistribution structures 62 and 162 along the back side of the dies 50 and 150, respectively.

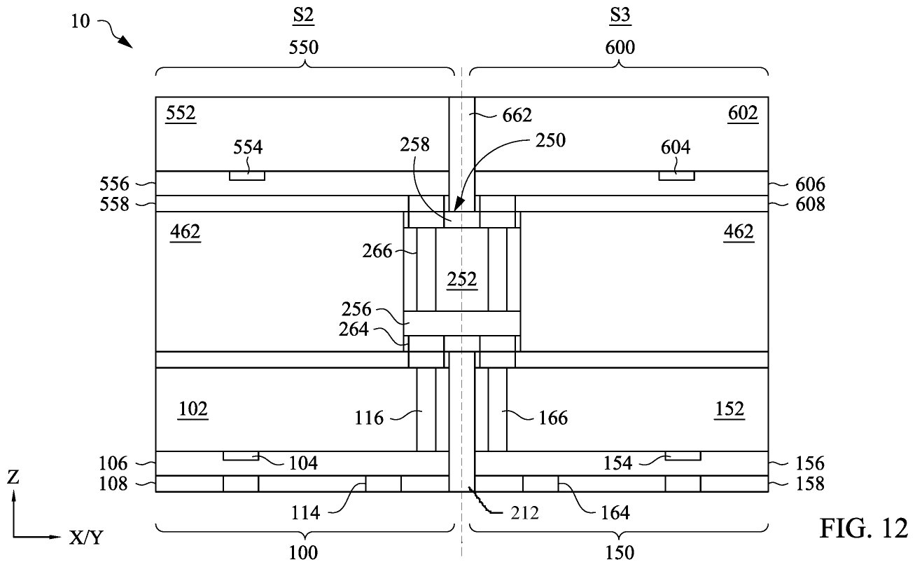

FIG. 12 illustrates a cross-sectional view of the package component 10 along line BB′ as shown in FIG. 7. In the depicted embodiment, the semiconductor bridge 250 is disposed over and electrically coupled to the dies 100 and 150 and interposed between portions of the gap-fill layer 462, and the dies 500 and 600 are disposed over and electrically coupled to the semiconductor bridge 250. Furthermore, the semiconductor bridge 250 further includes the TSVs 266, allowing the semiconductor bridge 250 to electrically couple the die 100 to the die 600 and the die 150 to the die 500, similar to the embodiments depicted in FIGS. 8-11. As such, in addition to affording four-way die-to-die communication between dies of non-adjacent stacks (e.g., the stacks S1 and S3 or the stacks S2 and S4), the semiconductor bridge 250 also allows two-way communication between dies in the same tier of laterally adjacent (i.e., side-by-side) stacks (e.g., the stacks S2 and S3).

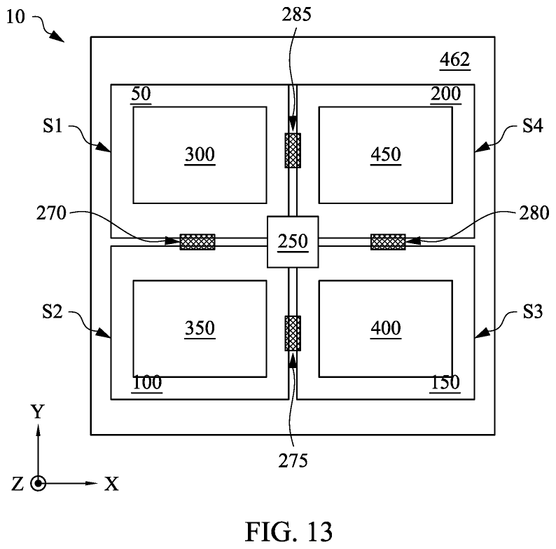

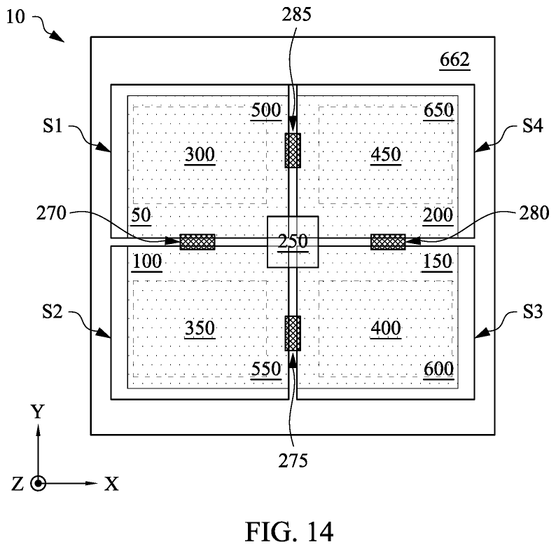

In some embodiments, referring to FIGS. 13 and 14, which correspond to FIGS. 1 and 7, respectively, the package component 10 includes additional semiconductor bridges 270, 275, 280, and 285 disposed along edges, rather than over corners, of adjacent dies. In this regard, the semiconductor bridges 270-285 are configured to electrically couple laterally adjacent dies disposed in the same layer, each offering two-way die-to-to communication. For example, the semiconductor bridge 270 may be disposed along edges of the dies 50 and 100, the semiconductor bridge 275 may be disposed along edges of the dies 100 and 150, the semiconductor bridge 280 may be disposed along edges of the dies 150 and 200, and the semiconductor bridge 285 may be disposed along edges of the dies 200 and 50.

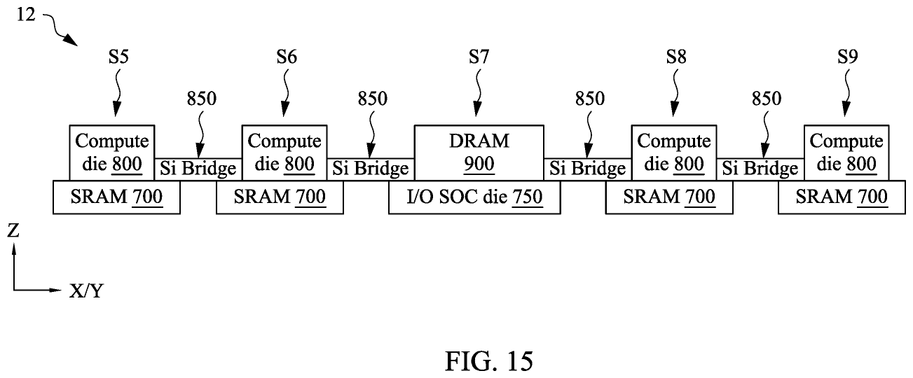

FIG. 15 illustrates an embodiment of an example package component 12 that includes dies of different functions interconnected by one or more semiconductor bridges to form a heterogeneous chip. The structure of the package component 12 may be analogous to that of the package component 10 as shown in FIGS. 1-4. For example, the package component 12 may include stacks S5, S6, S7, S8, and S9 arranged across the X-Y plane and laterally interconnected by semiconductor bridges (or Si bridge) 850, where each semiconductor bridge 850 electrically couples two SRAM dies 700 or an SRAM die 700 and an I/O system-on-a-chip (SoC) die 750.

In some examples, additional stacks (not depicted) may be provided and the stacks may be arranged in a corner-to-corner configuration, such that the semiconductor bridges 850 are each positioned to overlap the corners of the dies in different stacks. In this regard, the semiconductor bridges 850 may provide benefits, including four-way die-to-die communication, similar to those provided by the semiconductor bridge 250 as discussed in detail above. Furthermore, by incorporating back-side redistribution structures (not depicted; similar to the redistribution structures 62 and 162 depicted in FIG. 3) in the SRAM dies 700 and the I/O SoC die 750, the four-way communication may be improved by shortened conduction paths. For example, the conduction path between two compute dies 800 or between a compute die 800 and a DRAM die 900 of adjacent stacks may be shortened for improved device gain.

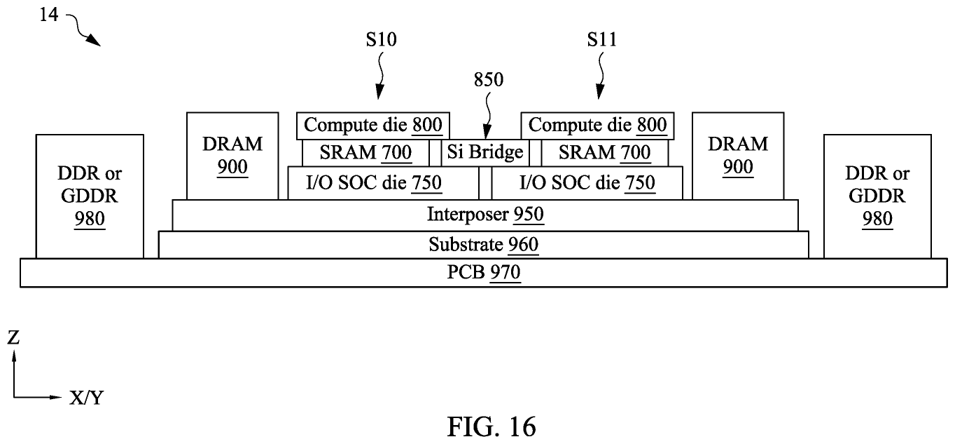

FIG. 16 illustrate an embodiment of a package component 14 that includes dies of different functions interconnected by one or more semiconductor bridges to form a heterogeneous chip. The package component 14, as shown here, may include similar dies as those of the package component 12, although such components may be arranged differently based on different design requirements. In the depicted embodiment, the structure of the package component 14 may be analogous to that of the package component 10 as shown in FIGS. 7-12. For example, the package component 14 may include stacks S10 and S11 arranged across the X-Y plane and laterally interconnected by the semiconductor bridges (or silicon bridge) 850, where each semiconductor bridge 850 electrically couples the two I/O SoC dies 750 together and is electrically coupled to each of the two compute dies 800.

In some examples, additional stacks (not depicted) may be provided and the stacks may be arranged in a corner-to-corner configuration, such that the semiconductor bridge 850 is positioned to overlap the corners of the dies in different stacks. In this regard, the semiconductor bridges 850 may provide benefits, including four-way die-to-die communication, similar to those provided by the semiconductor bridge 250 as discussed in detail above. Furthermore, by incorporating a back-side redistribution structure (not depicted; similar to the redistribution structure 262 depicted in FIGS. 9 and 10) in the semiconductor bridge 850, the two compute dies 800 may be electrically coupled along a shortened conduction path similar to that discussed above with respect to FIG. 9, improving the device performance accordingly. Still further, the die-to-die communication may be further improved by incorporating back-side redistribution structures (not depicted; similar to the redistribution structures 62 and 162 depicted in FIGS. 10 and 11) in the I/O SoC dies 750 similar to that discussed above with respect to FIG. 10.

In some examples, additional components such as an interposer 950, a substrate 960, a printed circuit board (PCB) 970, and double date rate (DDR) or graphic DDR (GDDR) memory components 980 may be electrically coupled or otherwise bonded to the above-mentioned dies to form the package component 14, according to various design requirements.

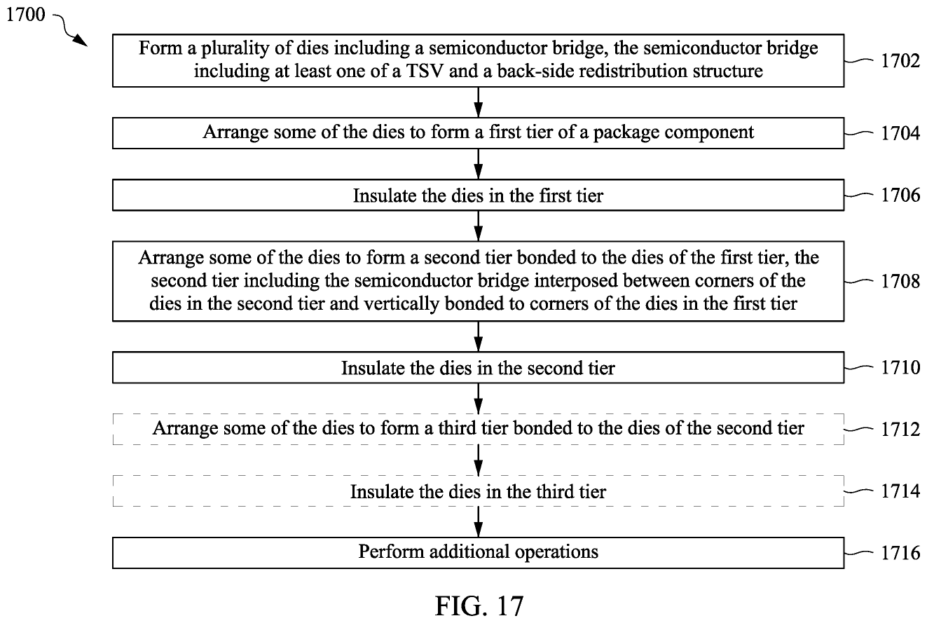

FIG. 17 is a flow diagram of a method 1700 for the fabrication of a semiconductor device, such as the package component 10, according to some embodiments. The method 1700 may be used to fabricate a semiconductor device having a plurality of semiconductor dies interconnected by one or more silicon bridges and one or more redistribution structures. For example, at least some of the operations described in the method 1700 may result in the package component 10, or portions thereof, depicted in FIGS. 1-16. The method 1700 is disclosed as a non-limiting example, and additional operations may be provided before, during, and after the method 1700 of FIG. 17. Furthermore, some operations may only be described briefly herein, though it is understood that the disclosed method may be performed in conjunction with other disclosed methods. For example, it is understood that additional layers, terminals, spacers, under-fills, and semiconductor bridges can be connected to the package component 10.

At operation 1702, the method 1700 forms a plurality of dies, such as the dies 50-650 of the package component 10, including the semiconductor bridge 250.

Each of the dies provided herein may be a logic die (e.g., central processing unit (CPU), graphics processing unit (GPU), an SoC, application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

Each die may have a semiconductor substrate (e.g., the semiconductor substrates 52, 152, 252, 302, 402, 502, and 602) that includes, for example, silicon, doped or undoped, or an active layer of a semiconductor-on-insulator (SOI) substrate. The semiconductor substrate may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used. The semiconductor substrate may have an active surface or a front side, and an inactive surface or a back side.

Devices (e.g., the device features 54, 154, 304, 404, 504, and 604) may be disposed at the active surface of the semiconductor substrate. The devices may be active devices (e.g., transistors, diodes, etc.), capacitors, resistors, or the like. A multi-layer interconnect structure or MLI (e.g., 56, 156, 256, 306, 406, 506, and 606) may be disposed over the active surface of the semiconductor substrate. The MLI may interconnect the devices to form an integrated circuit. The MLI may be formed of metallization patterns in dielectric layers. The dielectric layers may be low-k dielectric layers. The metallization patterns may include metal lines and vias, which may be formed in the dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns are electrically coupled to the devices.

TSVs (e.g., the TSVs 66, 166, 266, 316, and 426) may be disposed in the semiconductor substrate. The TSVs may be electrically coupled to the metallization patterns of the MLI. The semiconductor substrate may be thinned in a subsequent process to expose the TSVs at the inactive surface of the semiconductor substrate. After the thinning process, the conductive vias may be through-substrate vias, such as through-silicon vias (TSV).

A bonding layer (e.g., the bonding layers 58, 158, 258, 308, 408, 508, and 608) may be disposed on the MLI at the front side of the die. The bonding layer may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a BCB-based polymer, or the like; a combination thereof; or the like. The bonding layer may be formed by chemical vapor deposition (CVD), atomic layer deposition (ALD), spin coating, lamination, or the like. One or more passivation layer(s) (not separately illustrated) may be disposed between the bonding layer and the MLI.

Bond pads (e.g., the bond pads 64, 164, 264, 314, 414, 514, and 614) may extend through the bonding layer. The bond pads may include conductive pillars, pads, or the like, to which external connections can be made. In some embodiments, the bond pads include bond pads at the front side each die and vias that connect the bond pads to the lower metallization pattern of the MLI. In such embodiments, the bond pads, including the bond pads and the vias, may be formed by a damascene process, such as a single damascene process, a dual damascene process, or the like. The bond pads may be formed of a conductive material, such as copper, aluminum, or the like, by a technique, such as plating or the like.

In some embodiments, such as those depicted in FIGS. 3 and 9-11, some of the dies (e.g., the die 50, the die 150, and the semiconductor bridge 250) include a redistribution structure (e.g., the redistribution structures 62, 162, and 262) formed along a back side of the respective dies. The redistribution structure may include a plurality of metallization patterns extending laterally (e.g., along the X-direction, the Y-direction, or both) and vertically along the Z-direction. The metallization patterns may be formed in one or more dielectric layers (e.g., the dielectric layers 57, 157, and 257) by a damascene process (e.g., a single damascene process or a double damascene process) or other suitable process. The metallization patterns include a conductive material, such as copper, aluminum, or the like, by a technique, such as plating or the like.

At operation 1704, the method 1700 arranges and attaches some of the plurality of dies (e.g., the dies 50-200) to form a first tier (i.e., the bottom tier) of the package component. In the present embodiments, the dies of the first tier are arranged in a corner-to-corner configuration, such that the scribe line L1 and the scribe line L2 separate the dies of the first tier as shown in FIGS. 1 and 7.

To form the bottom tier of the package component 10, four dies (e.g., the dies 50-200) are arranged and attached to a carrier (not depicted separately) by an adhesive (not depicted separately). The carrier may be a semiconductor carrier, a glass carrier, a ceramic carrier, or the like. The carrier may be a wafer. In some embodiments, the adhesive is a thermal-release layer, such as an epoxy-based light-to-heat-conversion (LTHC) release material, which loses its adhesive property when heated.

The various dies within a tier of the package component can be a repeating pattern of circuit elements (e.g., memory, compute, graphics, artificial intelligence optimized cores, etc.) such that additional dies increase a performance or capacity of a device. The various dies can execute unique functions (e.g., heterogeneous functions) such that the additional dies increase functionality of the device. The various dies can interoperate by standard or non-standard connections (e.g., physical and logical).

At operation 1706, the method 1700 insulate the dies of the first tier by forming a gap-fill layer (e.g., the gap-fill layer 212) between adjacent dies.

In some embodiments, the gap-fill layer is formed around the dies of the bottom tier. The gap-fill layer may be an insulating layer and may be formed of a dielectric material, such as silicon oxide, PSG, BSG, BPSG, a TEOS based oxide, or the like, which may be formed by a suitable deposition process such as CVD, ALD, or the like. In some embodiments, a thinning process such as a chemical-mechanical polishing (CMP) process, a grinding process, an etch-back process, combinations thereof, or the like, is utilized.

At operation 1708, the method 1700 arranges and attaches some of the plurality of dies (e.g., the semiconductor bridge 250 and the dies 300-450) to form a second tier (i.e., the middle tier) over and electrically coupled to the first tier of the package component.

In some embodiments, the method 1700 first forms a bonding layer over the dies of the first tier. The bonding layer may be a dielectric layer formed on the gap-fill layer and the back sides of the dies of the first tier, and bond pads are formed in the bonding layer. The bonding layer may electrically isolate each of the TSVs, thus avoiding shorting, and may also be utilized in a subsequent bonding process. The bonding layer may be formed of an oxide such as silicon oxide, PSG, BSG, BPSG, a TEOS based oxide, or the like, which may be formed by a suitable deposition process such as CVD, ALD, or the like. Other suitable dielectric materials, such as a polyimide, PBO, an encapsulant, combinations thereof, or the like, may also be utilized. The bond pads may be formed by a damascene process, such as a single damascene process, a dual damascene process, or the like. The bond pads may be formed of a metal, such as copper, aluminum, or the like, which can be formed by plating or the like. In some embodiments, a planarization process such as a CMP, a grinding process, an etch-back process, combinations thereof, or the like, is performed on the bonding layer and the bond pads.

The dies of the second tier may be bonded to the bonding layer and the bond pads by placing the dies of the second tier by a pick-and-place process or the like, then bonding them to the bonding layer and the bond pads by hybrid bonding, which includes the bonding dielectric components to dielectric components and bonding metal components to metal components at the bonding interface.

In the present embodiments, the semiconductor bridge 250 is interposed between corners of the dies 300-450 and bonded to each of the underlying dies 50-200 in the first tier of the package component 10, where the semiconductor bridge 250 overlaps a corner of each of the dies 50-200.

The present embodiments illustrate a front-to-back bonding configuration as an example. For example, the back sides of the die 50 and the die 150 face the front sides of the die 300 and 400 after bonding. Other bonding configurations are contemplated, such as a front-to-front bonding configuration.

At operation 1710, the method 1700 insulate the dies of the second tier by forming a gap-fill layer (e.g., the gap-fill layer 462) between the dies. The process of insulating the dies of the second tier may be similar to that of insulating the dies of the first tier as discussed in detail above.

At operation 1712, the method 1700 arranges and attaches some of the plurality of dies (e.g., the dies 500-650) to form a third tier (i.e., the top tier) over and electrically coupled to the second tier of the package component. The process of attaching the dies of the third tier may be similar to that of attaching the dies of the first tier as discussed in detail above.

In the present embodiments, corners of the dies in the third tier overlap with the semiconductor bridge 250 and each of the dies in the third tier is bonded to the corresponding dies of the second tier. In this regard, vertically bonded dies in the first tier, the second tier, and the third tier form four stacks (e.g., the stacks S1-S4) arranged in a corner-to-corner configuration a shown in FIGS. 1 and 7.

At operation 1714, the method 1700 insulate the dies in the third tier by forming a gap-fill layer (e.g., the gap-fill layer 662) between the dies. The process of insulating the dies of the third tier may be similar to that of insulating the dies of the first tier as discussed in detail above.

In some embodiments, attaching and insulating the dies of the third tier is optional, i.e., the package component includes two tiers of dies interconnected laterally by a semiconductor bridge as shown in FIGS. 1-6. In this regard, the method 1700 may proceed from operation 1810 to 1716 directly.

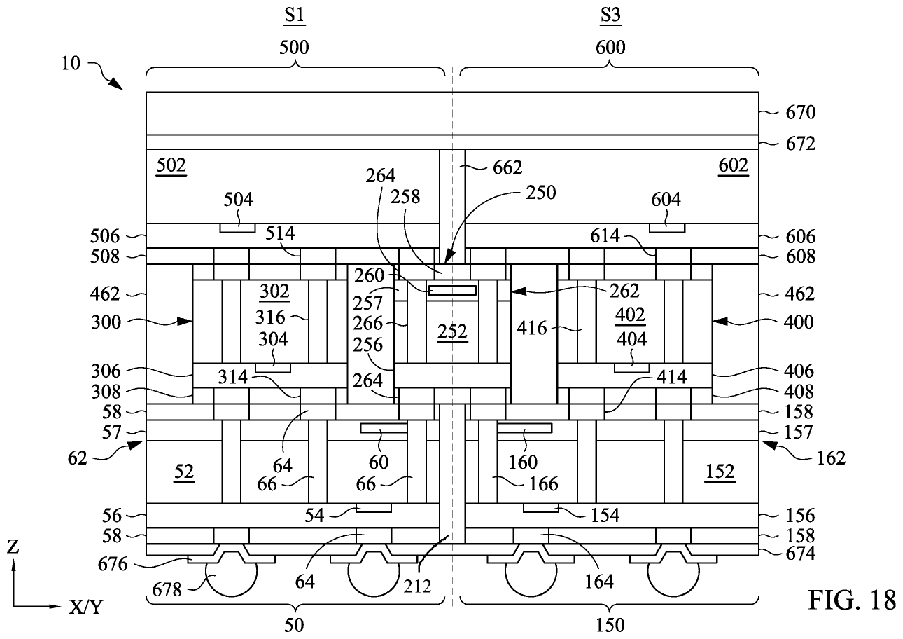

At operation 1716, the method 1700 performs additional operations to the package component 10 discussed above. Some aspects of the method 1700 discussed below are illustrated in a cross-sectional view of the package component 10, which corresponds to the embodiment depicted in FIG. 10. FIG. 18 is constructed for illustrative purposes only and the method 1700, in portion or in entirety, is applicable for fabricating other embodiments depicted or otherwise described herein.

Referring to FIG. 18, a carrier 670 is formed over the back side of the dies in the third tier (e.g., the dies 500-650) via a dielectric interface layer 672. The carrier may be a semiconductor carrier, a glass carrier, a ceramic carrier, or the like. The carrier may be a wafer having a same or similar size as the carrier disposed over the front side of the dies in the first tier (e.g., the dies 50-200). One or more bonding layers (not depicted separately) may be disposed on the carrier and configured to bond with a bonding layer (not depicted separately) formed over the backsides of the dies in the third tier to form the dielectric interface layer 672. The bonding layers that form the dielectric interface layer 672 may be similar to the bonding layers (e.g., the bonding layers 58, 158, 258, 308, 408, 508, and 608) discussed in detail above. The bonding layers may include a dielectric material, such as silicon dioxide, and may be formed by a suitable deposition process such as CVD, ALD, or the like.

Subsequently, referring to FIG. 18, the carrier is removed from and a dielectric layer 674 is formed over the front sides of the dies of the first tier. The removal process may include projecting a light beam such as a laser beam or a UV light beam to decompose the adhesive upon exposure. In some embodiments, the dielectric layer includes silicon dioxide, silicon nitride, or the like, and is formed by a suitable deposition process such as CVD, ALD, or the like. In some embodiments, the dielectric layer includes PBO, polyimide, a BCB-based polymer, or the like, and is formed by a suitable coating process such as spin coating, lamination, or the like.

Under-bump metallizations (UBMs) 676 and electrical connectors 678 are formed over the front sides of the dies in the first tier. The UBMs may have portions extending along a surface of the dielectric layer and portions extending through the dielectric layer to physically and electrically couple to the bond pads connected to the dies of the first tier (e.g., the bond pads 64 and 164). As a result, the UBMs are electrically coupled to the dies in the first tier. The UBMs may be formed by patterning (using a lithography technique, for example) the dielectric layer to expose the underlying bond pads in openings and form a conductive layer (including a seed layer in some examples) in the openings by one or more suitable deposition processes. The conductive layer may include a metal or a metal alloy, such as copper, titanium, tungsten, aluminum, other metals, or combinations thereof.

Electrical connectors 678 may be formed on the UBMs 676. The electrical connectors 220 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the electrical connectors 678 include a conductive material such as solder, copper, aluminum, gold, nickel, silver, palladium, tin, other suitable metals, or combinations thereof. The electrical connectors 220 may be formed by initially forming a layer of solder through evaporation, electroplating, printing, solder transfer, ball placement, or the like. Once the layer of solder has been formed on the structure, a reflow may be performed to shape the solder into the desired bump shapes. In some embodiments, the electrical connectors 220 include metal pillars, such as a copper pillar, formed by a sputtering, printing, electroplating, electroless plating, CVD, or the like, which are solder free and have substantially vertical sidewalls. A metal cap layer may be formed on top of the metal pillars.

Thereafter, a singulation process may be performed by placing the package component 10 on a tape (not depicted) supported by a frame (not depicted). The package component 10 may be then singulated along scribe lines (e.g., the scribe lines L1 and L2) to form a discreet package component separated from other portions of a wafer upon which the package component 10 is formed. The singulation process may include a sawing process, a laser cutting process, or the like. A cleaning process or rinsing process may be performed after the singulation process. Subsequently, the singulated package component may be bonded to a package substrate (not depicted) and an underfill (not depicted) may be formed between the singulated package component and the package substrate.

In one aspect of the present disclosure, a semiconductor package is disclosed. The semiconductor package includes a first semiconductor die and a second semiconductor die disposed adjacent one another. The semiconductor package includes a semiconductor bridge overlapping a first corner of the first semiconductor die and a second corner of the second semiconductor die. The semiconductor bridge electrically couples the first semiconductor die to the second semiconductor die. The semiconductor package includes a third semiconductor die and a fourth semiconductor die electrically coupled to the first semiconductor die and the second semiconductor die, respectively. The semiconductor bridge is interposed between the third semiconductor die and the fourth semiconductor die.

In another aspect of the present disclosure, a semiconductor package is disclosed. The semiconductor package includes a first semiconductor die and a second semiconductor die disposed adjacent one another. The semiconductor package includes a semiconductor bridge overlapping a first corner of the first semiconductor die and a second corner of the second semiconductor die. The semiconductor bridge electrically couples the first semiconductor die to the second semiconductor die. The semiconductor bridge includes a first via electrically coupled to the first semiconductor die and a second via electrically coupled to the second semiconductor die. The first via and the second via extend through a substrate of the semiconductor bridge. The semiconductor package includes a third semiconductor die and a fourth semiconductor die disposed over and electrically coupled to the semiconductor bridge. The semiconductor bridge is interposed between the third semiconductor die and the fourth semiconductor die. The third semiconductor die is electrically coupled to the first semiconductor die through the first via. The fourth semiconductor die is electrically coupled to the second semiconductor die through the second via.

In yet another aspect of the present disclosure, a semiconductor package is disclosed. The semiconductor package includes a first semiconductor die and a second semiconductor die disposed adjacent one another. The semiconductor package includes a semiconductor bridge overlapping a first corner of the first semiconductor die and a second corner of the second semiconductor die. The semiconductor bridge electrically couples the first semiconductor die to the second semiconductor die. The semiconductor package includes a third semiconductor die and a fourth semiconductor die disposed over and electrically coupled to the semiconductor bridge. The semiconductor bridge is interposed between the third semiconductor die and the fourth semiconductor die. The third semiconductor die and the fourth semiconductor die overlap a third corner and a fourth corner of the semiconductor bridge, respectively.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package, comprising:
a first semiconductor die and a second semiconductor die disposed adjacent one another;
a semiconductor bridge overlapping a first corner of the first semiconductor die and a second corner of the second semiconductor die, wherein the semiconductor bridge electrically couples the first semiconductor die to the second semiconductor die; and
a third semiconductor die and a fourth semiconductor die electrically coupled to the first semiconductor die and the second semiconductor die, respectively, wherein the semiconductor bridge is interposed between the third semiconductor die and the fourth semiconductor die.

2. The semiconductor package of claim 1, wherein the first semiconductor die and the third semiconductor die are coupled at a first bonding interface layer, and the second semiconductor die and the fourth semiconductor die are coupled at a second bonding interface layer.

3. The semiconductor package of claim 1, wherein the semiconductor bridge is laterally separated from the third semiconductor die and the fourth semiconductor die by a gap-fill layer.

4. The semiconductor package of claim 1, wherein the third semiconductor die and the fourth semiconductor die are disposed over and overlap with corners of the semiconductor bridge.

5. The semiconductor package of claim 4, further comprising a fifth semiconductor die vertically sandwiched between the first semiconductor die and the third semiconductor die and a sixth semiconductor die vertically sandwiched between the second semiconductor die and the fourth semiconductor die, wherein the semiconductor bridge is interposed between the fifth semiconductor die and the sixth semiconductor die.

6. The semiconductor package of claim 1, wherein the semiconductor bridge includes a first via and a second via extending through a substrate of the semiconductor bridge.

7. The semiconductor package of claim 6, the first semiconductor die and the third semiconductor die are coupled through the first via and the second semiconductor die and the fourth semiconductor die are coupled through the second via.

8. The semiconductor package of claim 1, further comprising a first redistribution structure disposed on a back side of the first semiconductor die and a second redistribution structure disposed on a back side of the second semiconductor die, wherein each of the first redistribution structure and the second redistribution structure includes a plurality of conductive features such that the third semiconductor die is electrically coupled to the second semiconductor die via the first redistribution structure and the fourth semiconductor die is electrically coupled to the first semiconductor die via the second redistribution structure.

9. The semiconductor package of claim 8, wherein the semiconductor bridge includes a first via and a second via extending through a substrate of the semiconductor bridge.

10. A semiconductor package, comprising:
a first semiconductor die and a second semiconductor die disposed adjacent one another;
a semiconductor bridge overlapping a first corner of the first semiconductor die and a second corner of the second semiconductor die, wherein the semiconductor bridge electrically couples the first semiconductor die to the second semiconductor die, and wherein the semiconductor bridge includes a first via electrically coupled to the first semiconductor die and a second via electrically coupled to the second semiconductor die, the first via and the second via extending through a substrate of the semiconductor bridge; and
a third semiconductor die and a fourth semiconductor die disposed over and electrically coupled to the semiconductor bridge, wherein the semiconductor bridge is interposed between the third semiconductor die and the fourth semiconductor die, wherein the third semiconductor die is electrically coupled to the first semiconductor die through the first via, and wherein the fourth semiconductor die is electrically coupled to the second semiconductor die through the second via.

11. The semiconductor package of claim 10, wherein the semiconductor bridge includes a redistribution structure disposed on its back side.

12. The semiconductor package of claim 10, further comprising a first redistribution structure disposed on a back side of the first semiconductor die and a second redistribution structure disposed on a back side of the second semiconductor die, wherein each of the first redistribution structure and the second redistribution structure includes a plurality of conductive features such that the third semiconductor die is electrically coupled to the second semiconductor die via the first redistribution structure and the fourth semiconductor die is electrically coupled to the first semiconductor die via the second redistribution structure.

13. The semiconductor package of claim 12, wherein the semiconductor bridge includes a third redistribution structure on its back side.

14. The semiconductor package of claim 10, wherein the first corner and the second corner are laterally offset from one another.

15. The semiconductor package of claim 10, wherein the semiconductor bridge is a first semiconductor bridge, further comprising a second semiconductor bridge overlapping a first edge of the first semiconductor die and a second edge of the semiconductor die, wherein the second semiconductor bridge electrically couples the first semiconductor die to the second semiconductor die.

16. The semiconductor package of claim 10, wherein the semiconductor bridge is laterally separated from the third semiconductor die and the fourth semiconductor die by a gap-fill layer.

17. The semiconductor package of claim 10, wherein the third semiconductor die and the fourth semiconductor die are over the semiconductor bridge, and wherein the third semiconductor die and the fourth semiconductor die each overlap a corner of the semiconductor bridge.

18. A method of fabricating a semiconductor package, comprising:
forming a plurality of dies including a semiconductor bridge, the semiconductor bridge including at least one of a through-substrate via (TSV) and a back-side redistribution structure;
forming a first tier of a package component, the first tier including a first subset of the dies;
insulating the first subset of the dies in the first tier;
forming a second tier of the package component electrically coupled to the first tier, the second tier including the semiconductor bridge interposed between corners of a second subset of the dies, wherein the semiconductor bridge is electrically coupled to corners of the first subset of the dies in the first tier; and
insulating the semiconductor bridge and the second subset of the dies in the second tier.

19. The method of claim 18, further comprising:
forming a third tier of the package component electrically coupled to the second tier, the third tier including a third subset of the dies each electrically coupled to a corner of the semiconductor bridge; and
insulating the third subset of the dies in the third tier.

20. The method of claim 18, wherein the first subset of the dies and the second subset of the dies each include four dies.
